(19) United States
(12) Patent Application Publication
(10) Pub. No.: US 2023/0251943 A1
(43) Pub. Date: Aug. 10, 2023

(54) ROW REPAIR AND ACCURACY IMPROVEMENTS IN ANALOG COMPUTE-IN-MEMORY ARCHITECTURES

(71) Applicant: Intel Corporation, Santa Clara, CA (US)

(72) Inventors: Richard Dorrance, Hillsboro, OR (US); Renzhi Liu, Portland, OR (US); Hechen Wang, Portland, OR (US); Deepak Dasalukunte, Beaverton, OR (US); Brent Carlton, Portland, OR (US)

(21) Appl. No.: 18/298,906

(22) Filed: Apr. 11, 2023

(51) Int. Cl. G06F 11/20

(52) U.S. Cl. CPC G06F 11/2041

(57) ABSTRACT

Systems, apparatuses and methods may provide for technology that includes a plurality of analog to digital converters (ADCs), compute-in-memory (CiM) multiply-accumulate (MAC) hardware coupled to the plurality of ADCs, and a plurality of digital to analog converters (DACs) coupled to the CiM MAC hardware, wherein the plurality of DACs includes one or more redundant DACs. In one example, the technology uses a DAC disconnect scheme to statically bypass defective memory bitcells and compute capacitors to improve yield with minimal overhead, and dynamically boost the effective precision of the ADC in the presence of weight/activation sparsity in neural network (NN) compute.

### TECHNICAL FIELD

Embodiments generally relate to artificial intelligence (AI) applications. More particularly, embodiments relate to row repair and accuracy improvements in analog compute-in-memory (CiM) architectures for AI applications.

### BACKGROUND OF THE DISCLOSURE

A neural network (NN) can be represented as a structure that is a graph of several neuron layers flowing from one layer to the next. The outputs of one layer of neurons can be based on calculations, and are the inputs of the next layer. To perform these calculations, a variety of matrix-vector, matrix-matrix, and tensor operations may be required, which are themselves comprised of many multiply-accumulate (MAC) operations. Indeed, there are so many of these MAC operations in a neural network, that such operations may dominate other types of computations (e.g., activation and pooling functions). The neural network operation may be enhanced by reducing data fetches from long term storage and distal memories separated from the MAC unit.

Compute-in-memory (CiM) static random-access memory (SRAM) architectures (e.g., merged memory and MAC units) may deliver increased efficiency to convolutional neural network (CNN) models as compared to near-memory computing architectures due to reduced latencies associated with data movement. A notable trend in CiM processor architectures may be to use capacitor-based analog mixed-signal (AMS) hardware when performing MAC operations (e.g., multiplying analog input activations by digital weights and accumulating the result) in a CNN model. CiM processors with AMS hardware may still experience, however, a loss in yield due to increased process, voltage and temperature (PVT) variations in more advanced process nodes and/or a loss in precision due to activation/weight sparsity.

### BRIEF DESCRIPTION OF THE DRAWINGS

The various advantages of the embodiments will become apparent to one skilled in the art by reading the following specification and appended claims, and by referencing the following drawings, in which:

FIG. 1 is a schematic diagram of an example of a digital to analog converter (DAC) disconnect scheme for row repair in compute-in-memory (CiM) architectures according to an embodiment;

FIG. 2A is a schematic diagram of a comparative example of capacitive loops for different DAC disconnect switch configurations;

FIG. 2B is a schematic diagram of an example of a DAC disconnect switch configuration according to an embodiment;

FIG. 3A is an illustration of an example of a 4-layer multilayer perceptron (MLP) neural network according to an embodiment;

FIG. 3B is an illustration of an example of training results for a 4-layer MLP neural network according to an embodiment;

FIG. 4A is a schematic diagram of an example of a DAC disconnect scheme for improved accuracy with activation/weight sparsity in CiM architectures without an ideal buffer according to an embodiment;

FIG. 4B is a schematic diagram of an example of switch parasitic capacitance according to an embodiment;

FIGS. 5 and 6 are flowcharts of examples of method of operating a performance-enhanced computing system according to an embodiment;

FIG. 7 is a block diagram of an example of a performance-enhanced computing system according to an embodiment;

FIG. 8 is an illustration of an example of a semiconductor package apparatus according to an embodiment;

FIG. 9 is a block diagram of an example of a processor according to an embodiment; and

FIG. 10 is a block diagram of an example of a multi-processor based computing system according to an embodiment.

### DETAILED DESCRIPTION

As already noted, compute-in-memory (CiM) processors with analog mixed-signal (AMS) hardware may experience a loss in yield due to increased process, voltage and temperature (PVT) variations in more advanced process nodes. For example, due to the tightly coupled nature of CiM, a single defect in a memory bitcell or compute capacitor may be enough to render an entire CiM array inoperable. Additionally, process mismatches can adversely affect the computational speed and accuracy of the array. These effects can in turn can have a negative impact on the area, energy, and cost efficiency of analog CiM (e.g., potentially, negating the benefits of analog CiM).

As also already noted, CiM processors with AMS hardware may experience a loss in precision due to activation/weight sparsity. Due to the classical tradeoff between ADC resolution and ADC conversion speed, certain analog CiM solutions may accept some small loss in precision/accuracy (e.g., for some fixed ADC precision). Such a design optimization, however, is typically made under the assumption that compute operations are 1) dense and 2) normalized to exercise the full range of the ADC. Unfortunately, that is not the case due to the existence of nonlinear activation functions (e.g., rectified linear unit/ReLU functions) and the truncation of near-zero weights to zero, which introduces a significant level of sparsity into the system.

To address these challenges, the technology described herein introduces a DAC disconnect scheme that can be used to: 1) statically bypass defective memory bitcells and compute capacitors to improve yield with minimal overhead; and 2) dynamically boost the effective precision of the ADC in the presence of weight/activation sparsity in neural network (NN) compute. More particularly, embodiments enable row repair functionality within a CiM array to bypass a defective memory bitcell or compute capacitor, by statically disconnecting the input activation DAC. Similarly, the ability to dynamically disconnect the DAC allows for improved digitization range on the analog MAC value at the ADC by effectively skipping “multiply-by-zero” operations (e.g., disconnecting the unused “zero” capacitors during capacitive charge sharing/summation operations). Accordingly, the technology described herein addresses two significant challenges of analog CiM when compared to existing digital accelerators: 1) yield loss due to PVT variation; and 2) accuracy/precision loss due to activation/weight sparsity.

### Yield Improvements

In general, redundant rows and columns may be used to boost the yield, reduce leakage, and improve performance in static random access memory (SRAM) arrays. Due to the tightly coupled nature of CiM systems, however, traditional memory repair techniques cannot be applied. Instead, defects may traditionally be treated as a yield/performance issue in the compute data path, leading to reduced area, energy, and cost efficiency. Table I below shows the SRAM yield vs. bitcell yield for different numbers of redundant rows for a 32 Kilobit (Kbit) SRAM macro. Without redundant rows, for even bitcell yields as high as 99.999%, sufficiently high macro yield cannot be achieved.

TABLE I

| | 32 Kbit SRAM Yield | | |
|---|---|---|---|
| Bitcell | 0 Redundant | 1 Redundant | 2 Redundant |
| Yield | Rows | Row | Rows |
| 99.99% | 3.77% | 15.83% | 35.39% |
| 99.999% | 72.06% | 95.61% | 99.52% |
| 99.9999% | 96.78% | 99.95% | 99.99994% |
| 99.99999% | 99.67% | 99.9995% | 99.9999994% |

For analog CiM applications, macro yield is additionally reduced by the addition of a compute capacitor. This loss in yield can be attributed to mismatch and PVT variations leading to both functional and performance failures (e.g., shorts, stuck-at-faults, loss of linearity, leakage, etc.). Table II shows the SRAM yield vs. bitcell yield for different numbers of redundant rows for a 32 Kbit CiM SRAM macro. Although a relatively high macro yield (99.63%) may be achieved without redundant rows, the yield significantly degrades in more advanced processes (e.g., 69.17%) due to increased mismatch and PVT variation. The addition of redundant rows therefore helps to maintain the yield of analog CiM in more advanced process nodes.

TABLE II

| | 32 Kbit SRAM Yield | | |
|---|---|---|---|
| Bitcell/Cap. | 0 Redundant | 1 Redundant | 2 Redundant |
| Yield | Rows | Row | Rows |
| 99.99% | 2.51% | 11.43% | 25.96% |
| 99.999% | 69.17% | 94.58% | 98.84% |
| 99.9999% | 96.38% | 99.93% | 99.992% |
| 99.99999% | 99.63% | 99.9993% | 99.99993% |

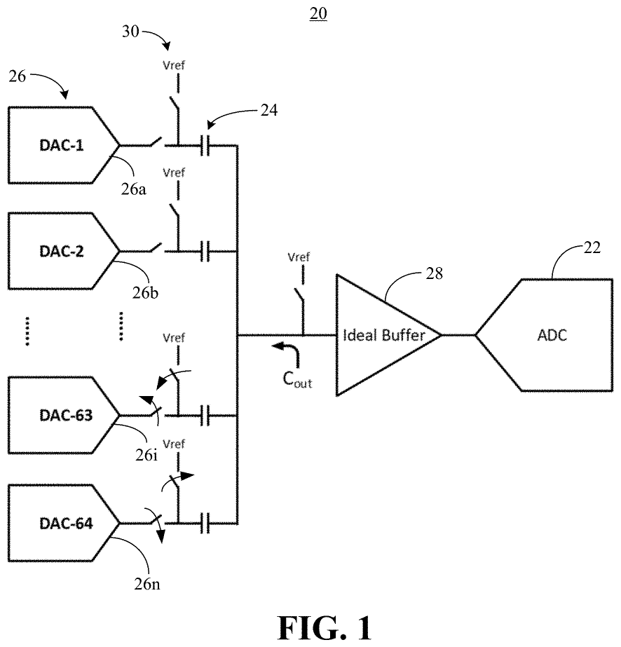

Turning now to FIG. 1, a processor 20 (e.g., AI accelerator) is shown in which CiM MAC hardware 24 (e.g., a plurality of compute capacitors) is coupled to an ADC 22 via an ideal buffer 28 and a plurality of DACs 26 (26a-26n, “DAC-1” through “DAC-64”) via a plurality of switch pairs 30, wherein the plurality of DACs 26 includes one or more redundant DACs such as, for example, DAC 26n. The illustrated example therefore presents a conceptual overview of a DAC 26 disconnect scheme for row repair in CiM with a single ADC 22 and 1-bit capacitive weights. This example can be easily extended to multiple ADCs 22 and multibit capacitive weights. Many of the practical design considerations for a realistic circuit implementation without the ideal buffer 28 will be discussed in greater detail. Operating in conjunction with traditional row remapping techniques (e.g., programmable register/fuse settings, address enable bits, etc.) for SRAM bitcells, each redundant row also has a redundant DAC 26n. When a fault or performance issue is detected with respect to a bitcell or compute capacitor within a row:
The affected row of SRAM bitcells are remapped to a redundant row by setting the fuses/programmable registers to the address of the impacted row. When a read or write takes place, and matches the fused addresses of the redundant row, then the main wordline (WL) decoder within the SRAM macro is disabled and the selected redundant row is enabled instead.
For the CiM side of the array, a DAC 26i on the affected row, for example, is disabled and disconnected from the array. For the MAC operation, inputs to the affected DAC 26i are remapped to the redundant DAC 26n on the redundant row.
With both the weights (e.g., stored in the SRAM) and the activations that are inputs to the affected DAC 26i rerouted, the analog CiM MAC hardware 24 proceeds normally. For a 32 Kbit CiM SRAM macro, the addition of one redundant row constitutes a minimal area overhead (e.g., 1.54%) for the macro, while two redundant rows results in a slightly greater overhead (e.g., 3.03%).

### Accuracy Improvements

For analog CiM, a significant challenge is to quantize the output activation (OA), which results from analog MAC computations, with sufficient quantization granularity (e.g., small enough quantization step) to not affect the machine learning (ML) inference accuracy. Traditional design optimizations for analog CiM, however, typically make two incorrect assumptions that the compute is 1) dense and 2) normalized to exercise the full range of the ADC. Unfortunately, neither is often the case due to nonlinear activation functions such as, for example, ReLU functions, and the truncation of near-zero weights to zero (e.g., introducing a significant level of sparsity into the system).

Embodiments therefore extend the “static” DAC disconnect scheme used to remap defective memory bitcells and compute capacitors to redundant rows to a “dynamic” case that exploits sparsity to reduce capacitive charge sharing and boost the dynamic range at the input of the ADC (e.g., if the input activation is zero, the row is disconnected from the array as it contributed nothing to the computation). A linear digital correction factor, based on the number of disconnected DACs, is used at the output of the ADC to correct for the variable amount of capacitance encountered during the charge sharing operation. This increased dynamic range leads to higher precision for smaller output values, where greater accuracy is advantageous for many nonlinear activation functions.

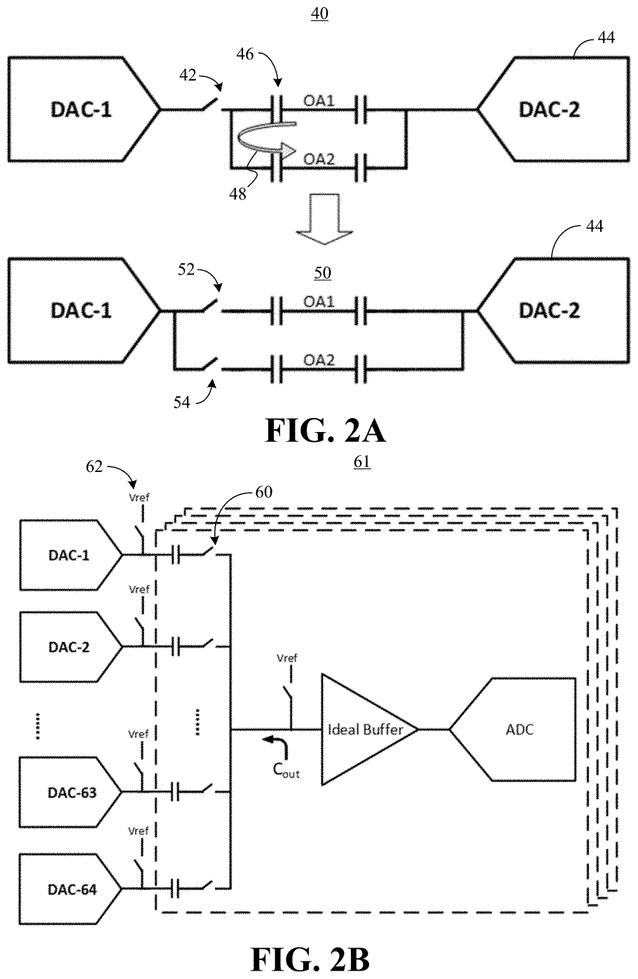

FIGS. 2A-2B demonstrates an issue that may be encountered by a first dynamic DAC disconnect scheme 40 when a single switch 42 is used for a DAC 44 with multiple fanouts (e.g., driving inputs to multiple ADCs, not shown). If the switch 42 is positioned on the bottom plate of a compute capacitor 46—resulting in sharing a single switch 42 per DAC 44—then capacitive loops 48 are created among the output activations (“OA1”, “OA2”). Such an approach may disrupt the charge sharing base MAC operation in analog CiM. By contrast, a second dynamic DAC disconnect scheme 50 uses multiple switches 52, 54 corresponding to the multiple output activations to eliminate the capacitive loops 48. As best seen in FIG. 2B, a DAC disconnect switch configuration 61 connects the switches 60 to the top plates of compute capacitors 62 in addition to providing one switch 60 per output activation to eliminate the capacitive loops 48 (FIG. 2A).

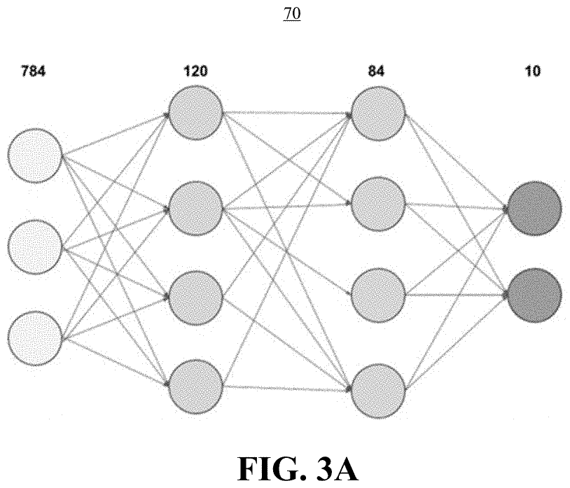

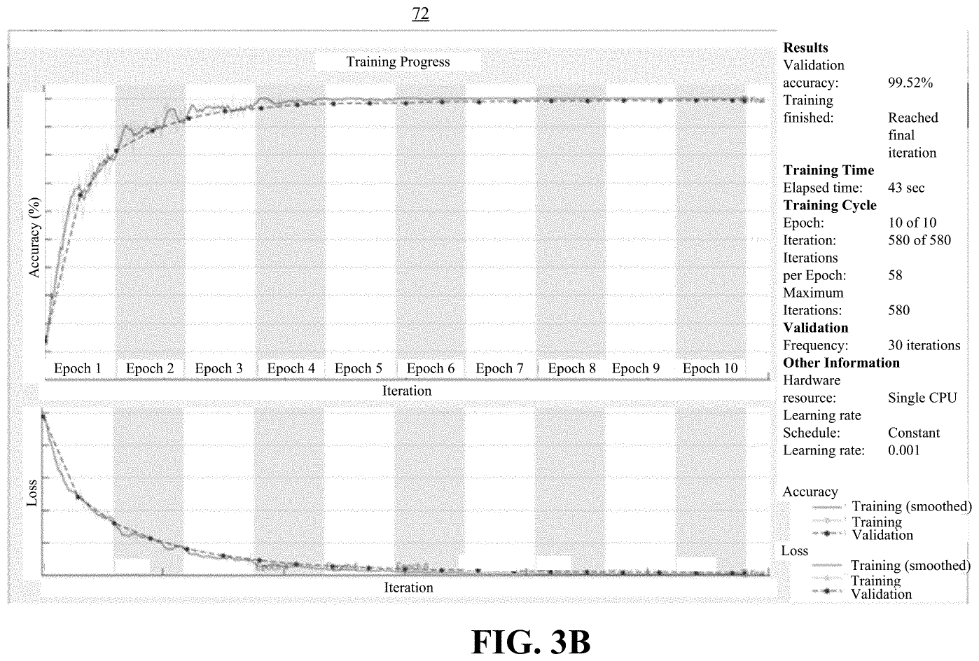

FIGS. 3A and 3B show an example of training results 72 for a 4-layer multilayer perceptron (MLP) neural network 70 (e.g., supplement of feed forward neural network) trained to classify handwritten digits between 0 and 9 (e.g., Modified National Institute of Standards and Technology/MNIST dataset) trained using a MATLAB Deep Learning Toolbox. The original network achieves 99.52% accuracy using single precision floating-point values. After quantizing the network to 8-bits, however, the accuracy drops to 65.55%±2.75%. This lost accuracy could be recovered with retraining, but at the cost of weeks to months of extra development and computational time. Using the DAC disconnect scheme described herein to counteract the sparsity introduced by the ReLU output activations (and zero padding introduced to fit the CiM dimensioning) the digitization range is boosted and most of the accuracy loss is recovered to 95.98% ±0.21%.

### ADC Compatibility Without a Buffer

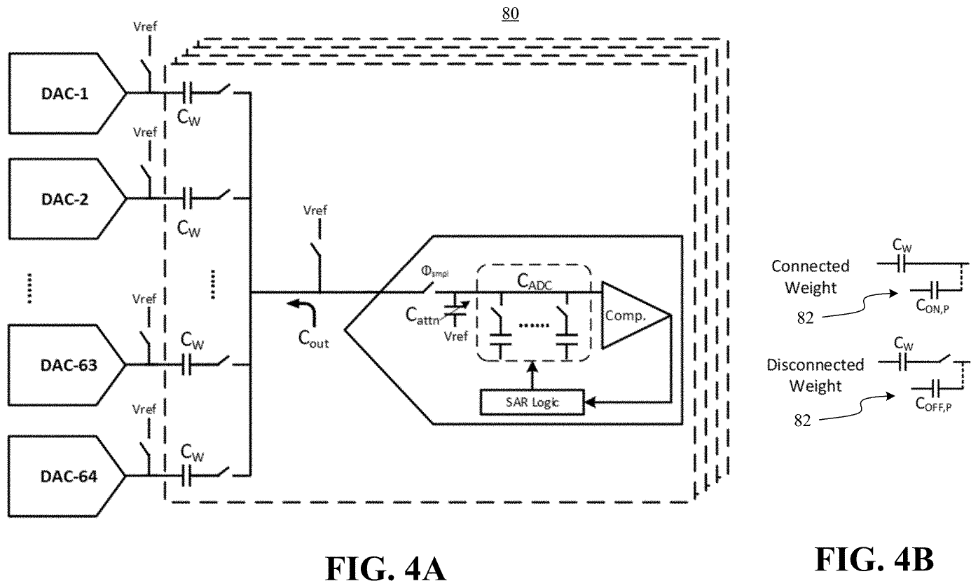

FIGS. 4A and 4B show a modified conceptual DAC disconnect scheme 80 for improved accuracy with sparsity in CiM without the ideal buffer 28 (FIG. 1). If Cₒᵤₜ=n·C_{W}, where C_{W} is the capacitance for each weight and n is the number non-zero DACs, then the appropriate scaling factors can be calculated as follows:
Assuming that the signal is scaled during the ADC sampling process, and that the ADC full-scale (FS) is also scaled, then:
Signal attenuation factor

$$\frac{{C}_{o u t}}{{C}_{o u t} + {C}_{a t t n} + {C}_{A D C}} ,$$

ADC FS scaling factor

$$\frac{C A D C}{C A D C + Cattn}$$

Overall digital scaling factor

$$DS = \frac{n {C}_{W} + {C}_{attn} + {C}_{A D C}}{n {C}_{W}} \frac{{C}_{A D C}}{{C}_{A D C} + {C}_{attn}} \frac{n}{64} ,$$

smaller the
Assume Cₐₜₜₙ=C_{ADC}, for a 0.5 ADC FS scaling,

$$DS = \frac{n {C}_{W} + 2 {C}_{A D C}}{128 {C}_{W}} = \frac{n}{128} + \frac{{C}_{ADC}}{64 {C}_{W}}$$

Also have constraint

$$\frac{{C}_{o u t}}{{C}_{o u t} + {C}_{a t t n} + {C}_{A D C}} \leq \frac{{C}_{A D C}}{{C}_{A D C} + {C}_{attn}} \to \frac{n {C}_{W}}{2} \leq {C}_{A D C} , or \frac{C out}{2} \leq$$

### C_{ADC}

C_{ADC} tracks

$$\frac{{C}_{o u t}}{2} ,$$

achieving min.

$$DS = \frac{n}{64}$$

Practical C_{ADC} programmability (layout) and tracking of Cₒᵤₜ
Compromise:

$${C}_{ADC} = {2}^{m} {C}_{w} with ( n / 2 \leq {2}^{m} < n ) , so \frac{{C}_{o u t}}{2} \leq {C}_{A D C} < {C}_{out}$$

The digital scaling factor would be between

$$\frac{n}{64} \leq D S < \frac{1.5 n}{64} ,$$

and could be calibrated for each n.

Additionally, when accounting for the switch parasitic capacitances 82, the following constraints can be further derived:
Attenuation when the C_{W} parasitic cap is considered:
Each C_{W} has parasitic cap C_{ON,P} when connected; and C_{OFF,P} when disconnected.
Worst-case assumption is C_{ON,P} is 0.5 C_{W} and C_{OFF,P} is 0.2 C_{W}
Overall parasitic capacitances: n·C_{ON,P}+(64−n)·C_{OFF,P}=0.3n·C_{W}+12.8C_{W}
Signal attenuation factor

$$\frac{n {C}_{W}}{1.3 n \cdot {C}_{W} + 12.8 {C}_{W} + {C}_{attn} + {C}_{A D C}}$$

may be problematic for small n! [symbol] E.g., n=4, attenuation factor<0.2; n=8, attenuation factor ˜0.25
ADC FS Scaling can alleviate the situation (to some extent)
ADC FS scaling factor

$$\frac{{C}_{A D C}}{{C}_{A D C} + {C}_{attn}}$$

can still potentially match signal attenuation [symbol]
Resulting in very large Cₐₜₜₙ, making both numbers very small
ADC reference voltage scaling may be used for another level of ADC FS scaling
More than half of ADC conversion range might still be lost for small n
The ultimate limiting factor, however, is noise: kT/C and comparator noise [symbol] E.g., 0.25 ADC FS scaling with 0.8V ADC reference has 1.5 mV LSB, use C_{ADC}+Cₐₜₜₙ>20fF for kT/C noise being smaller than quantization noise

Parasitic capacitances (“parasitics”) and thermal noise will limit the achievable precision gains for high input signal sparsity (>90% sparsity). A 4-8× effective gain in precision, however, is likely even at the crossover point.

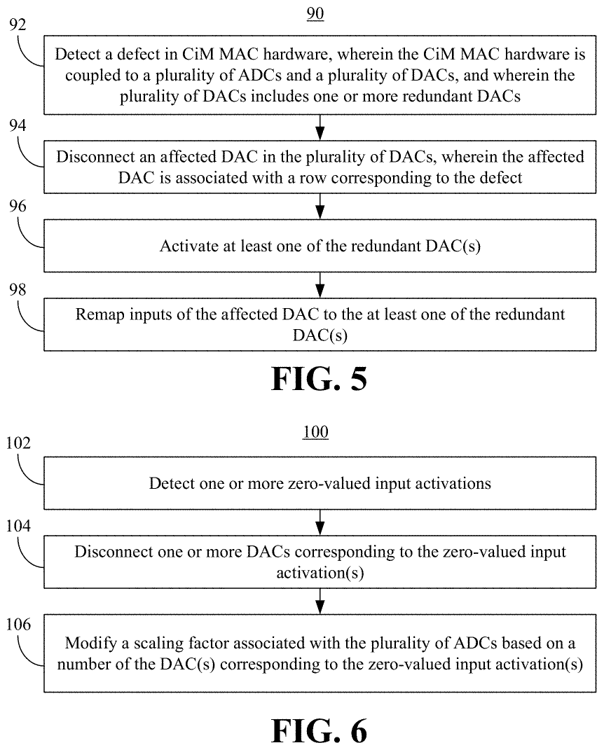

FIG. 5 shows a method 90 of operating a performance-enhanced computing system. The method 90 may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Computer program code to carry out operations shown in the method 90 can be written in any combination of one or more programming languages, including an object oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 92 provides for detecting (e.g., via a built-in self-test/BIST known pattern procedure) a defect in CiM MAC hardware, wherein the CiM MAC hardware is coupled to a plurality of ADCs and a plurality of DACs, and wherein the plurality of DACs includes one or more redundant DACs. In an embodiment, the defect is detected with respect to a bitcell and/or a capacitance (e.g., compute capacitor) in the CiM MAC hardware. The defective capacitance may be “explicit” (e.g., associated with two metal plates or other structure that specifically acts as a capacitor) and/or “implicit” (e.g., associated with the parasitic gate/wire capacitance of other devices). Block 94 disconnects an affected DAC in the plurality of DACs (e.g., in response to the defect), wherein the affected DAC is associated with a row corresponding to the defect. In one example, block 94 disconnects the affected DAC via one or more of a plurality of switches. In such a case, the plurality of switches may be positioned between capacitors (e.g., compute capacitors) in the CiM MAC hardware and the plurality of ADCs. Block 96 activates at least one of the redundant DAC(s), wherein block 98 remaps inputs of the affected DAC to the at least one of the redundant DAC(s). In one example, block 98 includes modifying one or more programmable register and/or fuse settings to set the addresses for remapping the rows with affected bitcells or capacitors and using enable bits to enable each redundant row. The method 90 therefore enhances performance at least to the extent that using redundant DACs to repair rows in CiM MAC hardware reduces yield loss due to PVT variation with minimal overhead.

FIG. 6 shows another method 100 of operating a performance-enhanced computing system. The method 100 may generally be implemented in conjunction with (e.g., when a defect has been detected), or separate from (e.g., when a defect has not been detected) the method 90 (FIG. 5), already discussed. More particularly, the method 100 may be implemented in one or more modules as a set of logic instructions stored in a machine- or computer-readable storage medium RAM, ROM, PROM, firmware, flash memory, etc., in hardware, or any combination thereof.

Illustrated processing block 102 provides for detecting one or more zero-valued input activations (IAs, e.g., zero output from a previous layer in a neural network). Block 104 disconnects one or more DACs corresponding to the zero-valued input activation(s). In general, the capacitance value of the MAC hardware may scale down when DACs are disconnected. Additionally, block 106 modifies a scaling factor associated with the plurality of ADCs based on a number of the DAC(s) corresponding to the zero-valued input activation(s). For example, if half of the DACs are disconnected due to zero-valued input activations, block 106 might double the dynamic range of the ADCs via the scaling factor. The method 100 therefore further enhances performance at least to the extent that disconnecting the zero-valued DACs and modifying the scaling factor of the ADCs dynamically boosts the effective precision of the ADCs in the presence of weight/activation sparsity in NN compute operations.

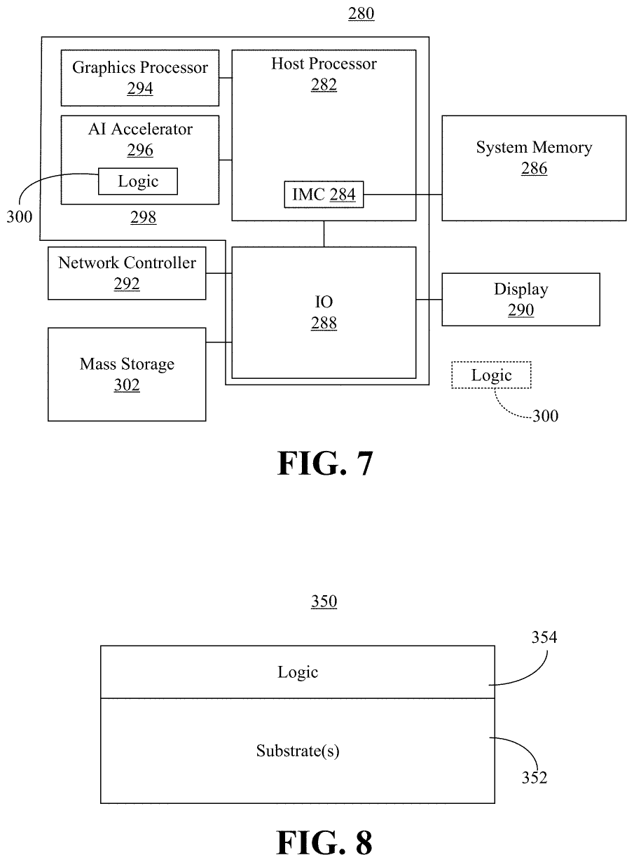

Turning now to FIG. 7, a performance-enhanced computing system 280 is shown. The system 280 may generally be part of an electronic device/platform having computing functionality (e.g., personal digital assistant/PDA, notebook computer, tablet computer, convertible tablet, edge node, server, cloud computing infrastructure), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, etc., or any combination thereof.

In the illustrated example, the system 280 includes a host processor 282 (e.g., central processing unit/CPU) having an integrated memory controller (IMC) 284 that is coupled to a system memory 286 (e.g., dual inline memory module/DIMM). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). The host processor 282 may be combined with the IO module 288, a graphics processor 294, and an AI accelerator 296 into a system on chip (SoC) 298.

In an embodiment, the AI accelerator 296 contains logic 300 including the processor 20 (FIG. 1), the DAC disconnect switch configuration 61 (FIG. 2B) and/or the DAC disconnect scheme 80 (FIG. 4A), already discussed. Thus, the logic 300 may include a plurality of ADCs, CiM MAC hardware coupled to the plurality of ADCs, and a plurality of DACs coupled to the CiM MAC hardware, wherein the plurality of DACs includes one or more redundant DACs. Although the logic 300 is shown within the AI accelerator 296, the logic 300 may reside elsewhere within the computing system 280.

In an embodiment, the logic 300 also performs one or more aspects of the method 90 (FIG. 5) and/or the method 100 (FIG. 6), already discussed. Thus, the logic 300 may detect a defect (e.g., explicit and/or implicit) in the CiM MAC hardware, disconnect an affected DAC in the plurality of DACs, wherein the affected DAC is associated with a row corresponding to the defect, activate at least one of the one or more redundant DACs, and remap inputs of the affected DAC to the at least one of the one or more redundant DACs. The computing system 280 is therefore considered performance-enhanced at least to the extent that using redundant DACs to repair rows in CiM MAC hardware reduces yield loss due to PVT variation with minimal overhead.

In one example, the logic 300 detects one or more zero-valued input activations, disconnects one or more DACs corresponding to the one or more zero-valued input activations, and modifies a scaling factor associated with the plurality of ADCs based on a number of the one or more DACs corresponding to the one or more zero-valued input activations. The computing system 280 is therefore further considered performance-enhanced at least to the extent that disconnecting the zero-valued DACs and modifying the scaling factor of the ADCs dynamically boosts the effective precision of the ADCs in the presence of weight/activation sparsity in NN compute operations.

FIG. 8 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. In an embodiment, the logic 354 implements one or more aspects of the method 90 (FIG. 5) and/or the method 100 (FIG. 6), already discussed.

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

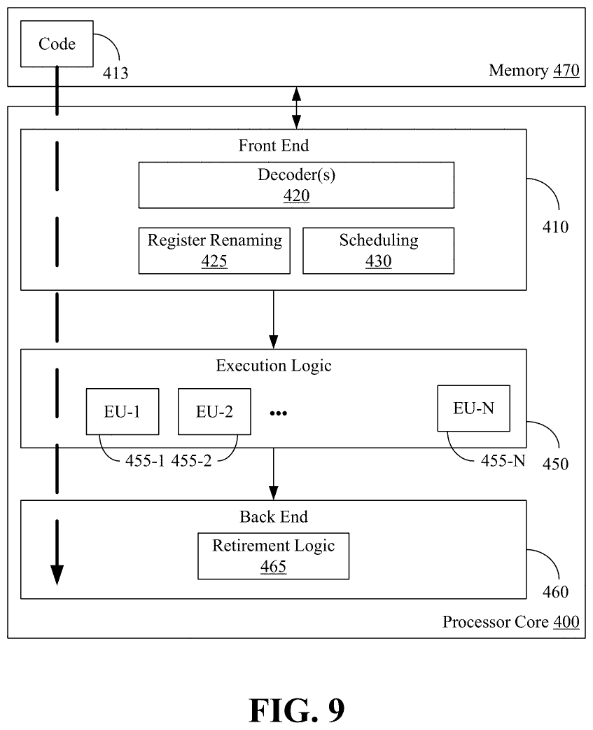

FIG. 9 illustrates a processor core 400 according to one embodiment. The processor core 400 may be the core for any type of processor, such as a micro-processor, an embedded processor, a digital signal processor (DSP), a network processor, or other device to execute code. Although only one processor core 400 is illustrated in FIG. 9, a processing element may alternatively include more than one of the processor core 400 illustrated in FIG. 9. The processor core 400 may be a single-threaded core or, for at least one embodiment, the processor core 400 may be multithreaded in that it may include more than one hardware thread context (or “logical processor”) per core.

FIG. 9 also illustrates a memory 470 coupled to the processor core 400. The memory 470 may be any of a wide variety of memories (including various layers of memory hierarchy) as are known or otherwise available to those of skill in the art. The memory 470 may include one or more code 413 instruction(s) to be executed by the processor core 400, wherein the code 413 may implement the method 90 (FIG. 5) and/or the method 100 (FIG. 6), already discussed. The processor core 400 follows a program sequence of instructions indicated by the code 413. Each instruction may enter a front end portion 410 and be processed by one or more decoders 420. The decoder 420 may generate as its output a micro operation such as a fixed width micro operation in a predefined format, or may generate other instructions, microinstructions, or control signals which reflect the original code instruction. The illustrated front end portion 410 also includes register renaming logic 425 and scheduling logic 430, which generally allocate resources and queue the operation corresponding to the convert instruction for execution.

The processor core 400 is shown including execution logic 450 having a set of execution units 455-1 through 455-N. Some embodiments may include a number of execution units dedicated to specific functions or sets of functions. Other embodiments may include only one execution unit or one execution unit that can perform a particular function. The illustrated execution logic 450 performs the operations specified by code instructions.

After completion of execution of the operations specified by the code instructions, back end logic 460 retires the instructions of the code 413. In one embodiment, the processor core 400 allows out of order execution but requires in order retirement of instructions. Retirement logic 465 may take a variety of forms as known to those of skill in the art (e.g., re-order buffers or the like). In this manner, the processor core 400 is transformed during execution of the code 413, at least in terms of the output generated by the decoder, the hardware registers and tables utilized by the register renaming logic 425, and any registers (not shown) modified by the execution logic 450.

Although not illustrated in FIG. 9, a processing element may include other elements on chip with the processor core 400. For example, a processing element may include memory control logic along with the processor core 400. The processing element may include I/O control logic and/or may include I/O control logic integrated with memory control logic. The processing element may also include one or more caches.

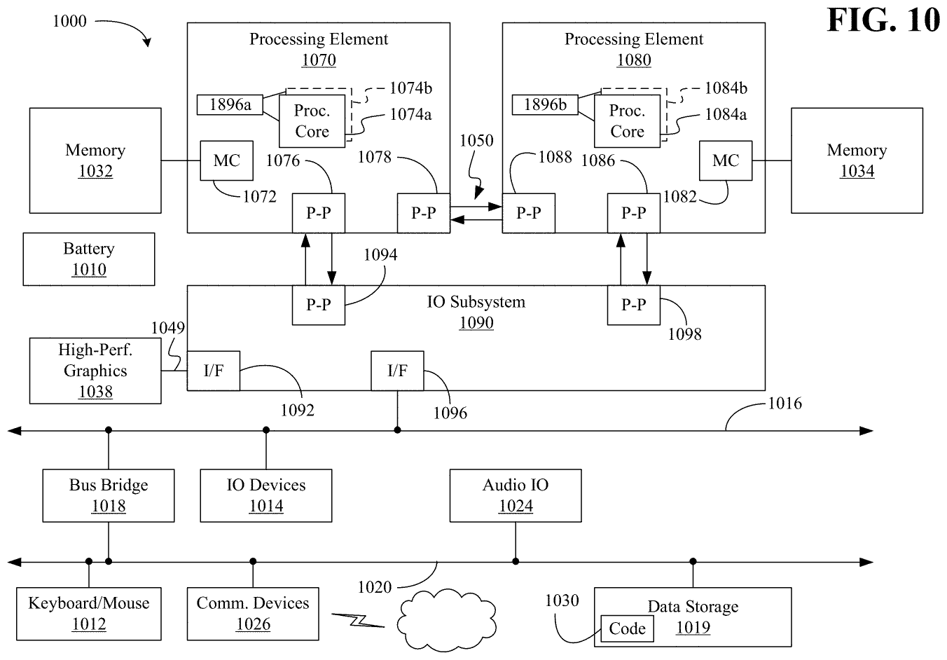

Referring now to FIG. 10, shown is a block diagram of a computing system 1000 embodiment in accordance with an embodiment. Shown in FIG. 10 is a multiprocessor system 1000 that includes a first processing element 1070 and a second processing element 1080. While two processing elements 1070 and 1080 are shown, it is to be understood that an embodiment of the system 1000 may also include only one such processing element.

The system 1000 is illustrated as a point-to-point interconnect system, wherein the first processing element 1070 and the second processing element 1080 are coupled via a point-to-point interconnect 1050. It should be understood that any or all of the interconnects illustrated in FIG. 10 may be implemented as a multi-drop bus rather than point-to-point interconnect.

As shown in FIG. 10, each of processing elements 1070 and 1080 may be multicore processors, including first and second processor cores (i.e., processor cores 1074a and 1074b and processor cores 1084a and 1084b). Such cores 1074a, 1074b, 1084a, 1084b may be configured to execute instruction code in a manner similar to that discussed above in connection with FIG. 9.

Each processing element 1070, 1080 may include at least one shared cache 1896a, 1896b. The shared cache 1896a, 1896b may store data (e.g., instructions) that are utilized by one or more components of the processor, such as the cores 1074a, 1074b and 1084a, 1084b, respectively. For example, the shared cache 1896a, 1896b may locally cache data stored in a memory 1032, 1034 for faster access by components of the processor. In one or more embodiments, the shared cache 1896a, 1896b may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the embodiments are not so limited. In other embodiments, one or more additional processing elements may be present in a given processor. Alternatively, one or more of processing elements 1070, 1080 may be an element other than a processor, such as an accelerator or a field programmable gate array. For example, additional processing element(s) may include additional processors(s) that are the same as a first processor 1070, additional processor(s) that are heterogeneous or asymmetric to processor a first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, micro architectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

The first processing element 1070 may further include memory controller logic (MC) 1072 and point-to-point (P-P) interfaces 1076 and 1078. Similarly, the second processing element 1080 may include a MC 1082 and P-P interfaces 1086 and 1088. As shown in FIG. 10, MC's 1072 and 1082 couple the processors to respective memories, namely a memory 1032 and a memory 1034, which may be portions of main memory locally attached to the respective processors. While the MC 1072 and 1082 is illustrated as integrated into the processing elements 1070, 1080, for alternative embodiments the MC logic may be discrete logic outside the processing elements 1070, 1080 rather than integrated therein.

The first processing element 1070 and the second processing element 1080 may be coupled to an I/O subsystem 1090 via P-P interconnects 1076 1086, respectively. As shown in FIG. 10, the I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, bus 1049 may be used to couple the graphics engine 1038 to the I/O subsystem 1090. Alternately, a point-to-point interconnect may couple these components.

In turn, I/O subsystem 1090 may be coupled to a first bus 1016 via an interface 1096. In one embodiment, the first bus 1016 may be a Peripheral Component Interconnect (PCI) bus, or a bus such as a PCI Express bus or another third generation I/O interconnect bus, although the scope of the embodiments are not so limited.

As shown in FIG. 10, various I/O devices 1014 (e.g., biometric scanners, speakers, cameras, sensors) may be coupled to the first bus 1016, along with a bus bridge 1018 which may couple the first bus 1016 to a second bus 1020. In one embodiment, the second bus 1020 may be a low pin count (LPC) bus. Various devices may be coupled to the second bus 1020 including, for example, a keyboard/mouse 1012, communication device(s) 1026, and a data storage unit 1019 such as a disk drive or other mass storage device which may include code 1030, in one embodiment. The illustrated code 1030 may implement the method 90 (FIG. 5) and/or the method 100 (FIG. 6), already discussed. Further, an audio I/O 1024 may be coupled to second bus 1020 and a battery 1010 may supply power to the computing system 1000.

Note that other embodiments are contemplated. For example, instead of the point-to-point architecture of FIG. 10, a system may implement a multi-drop bus or another such communication topology. Also, the elements of FIG. 10 may alternatively be partitioned using more or fewer integrated chips than shown in FIG. 10.

### ADDITIONAL NOTES AND EXAMPLES

Example 1 includes a performance-enhanced computing system comprising a network controller and a processor including one or more substrates and logic coupled to the one or more substrates, the logic including a plurality of analog to digital converters (ADCs), compute-in-memory (CiM) multiply-accumulate (MAC) hardware coupled to the plurality of ADCs, and a plurality of digital to analog converters (DACs) coupled to the CiM MAC hardware, wherein the plurality of DACs includes one or more redundant DACs.

Example 2 includes the computing system of Example 1, wherein the logic further includes a controller to detect a defect in the CiM MAC hardware, disconnect an affected DAC in the plurality of DACs, wherein the affected DAC is associated with a row corresponding to the defect, activate at least one of the one or more redundant DACs, and remap inputs of the affected DAC to the at least one of the one or more redundant DACs.

Example 3 includes the computing system of Example 2, wherein the logic further includes a plurality of switches, and wherein the affected DAC is disconnected via one or more of the plurality of switches.

Example 4 includes the computing system of Example 3, wherein the plurality of switches are positioned between capacitors in the CiM MAC hardware and the plurality of ADCs.

Example 5 includes the computing system of any one of Examples 1 to 4, wherein the instructions, when executed, further cause the computing system to detect one or more zero-valued input activations, disconnect one or more DACs corresponding to the one or more zero-valued input activations, and modify a scaling factor associated with the plurality of ADCs based on a number of the one or more DACs corresponding to the one or more zero-valued input activations.

Example 6 includes an apparatus comprising one or more substrates, and logic coupled to the one or more substrates, wherein the logic is implemented at least partly in one or more of configurable or fixed-functionality hardware, the logic including a plurality of analog to digital converters (ADCs), compute-in-memory (CiM) multiply-accumulate (MAC) hardware coupled to the plurality of ADCs, and a plurality of digital to analog converters (DACs) coupled to the CiM MAC hardware, wherein the plurality of DACs includes one or more redundant DACs.

Example 7 includes the apparatus of Example 6, wherein the logic further includes a controller to detect a defect in the CiM MAC hardware, disconnect an affected DAC in the plurality of DACs, wherein the affected DAC is associated with a row corresponding to the defect, activate at least one of the one or more redundant DACs, and remap inputs of the affected DAC to the at least one of the one or more redundant DACs.

Example 8 includes the apparatus of Example 7, wherein the logic further includes a plurality of switches, and wherein the affected DAC is disconnected via one or more of the plurality of switches.

Example 9 includes the apparatus of Example 8, wherein the plurality of switches are positioned between capacitors in the CiM MAC hardware and the plurality of ADCs.

Example 10 includes the apparatus of Example 7, wherein the controller is further to detect one or more zero-valued input activations, disconnect one or more DACs corresponding to the one or more zero-valued input activations, and modify a scaling factor associated with the plurality of ADCs based on a number of the one or more DACs corresponding to the one or more zero-valued input activations.

Example 11 includes the apparatus of any one of Examples 7 to 10, wherein the defect is detected with respect to a bitcell in the MAC hardware.

Example 12 includes the apparatus of any one of Examples 7 to 10, wherein the defect is detected with respect to a capacitance in the MAC hardware.

Example 13 includes the apparatus of any one of Examples 6 to 12, wherein the logic coupled to the one or more substrates includes transistor regions that are positioned within the one or more substrates.

Example 14 includes at least one computer readable storage medium comprising a set of instructions, which when executed by a computing system, cause the computing system to detect a defect in compute-in-memory (CiM) multiply-accumulate (MAC) hardware, wherein the CiM MAC hardware is coupled to a plurality of analog to digital converters (ADCs) and a plurality of digital to analog converters (DACs), and wherein the plurality of DACs includes one or more redundant DACs, disconnect an affected DAC in the plurality of DACs, wherein the affected DAC is associated with a row corresponding to the defect, activate at least one of the one or more redundant DACs, and remap inputs of the affected DAC to the at least one of the one or more redundant DACs.

Example 15 includes the at least one computer readable storage medium of Example 14, wherein the affected DAC is disconnected via one or more of a plurality of switches.

Example 16 includes the at least one computer readable storage medium of Example 15, wherein the plurality of switches are to be positioned between capacitors in the CiM MAC hardware and the plurality of ADCs.

Example 17 includes the at least one computer readable storage medium of Example 14, wherein the instructions, when executed, further cause the computing system to detect one or more zero-valued input activations, and disconnect one or more DACs corresponding to the one or more zero-valued input activations.

Example 18 includes the at least one computer readable storage medium of Example 17, wherein the instructions, when executed, further cause the computing system to modify a scaling factor associated with the plurality of ADCs based on a number of the one or more DACs corresponding to the one or more zero-valued input activations.

Example 19 includes the at least one computer readable storage medium of any one of Examples 14 to 18, wherein the defect is detected with respect to a bitcell in the CiM MAC hardware.

Example 20 includes the at least one computer readable storage medium of any one of Examples 14 to 18, wherein the defect is detected with respect to a capacitance in the CiM MAC hardware.

Example 21 includes a method comprising detecting one or more zero-valued input activations, disconnecting one or more digital to analog converters (DACs) corresponding to the one or more zero-valued input activations, and modifying a scaling factor associated with associated with a plurality of analog to digital converters (ADCs) based on a number of the one or DACs corresponding to the one or more zero-valued input activations.

Example 22 includes an apparatus comprising means for performing the method of Example 21.

Technology described herein therefore obviates any need to disable affected cores and bin the part as a lower performance product (e.g., treating defects as a yield/performance issue in the compute data path, leading to reduced area, energy, and cost efficiency). The technology described herein also provides a way to “skip” zeros in CiM architectures in the presence of nonlinear activation functions such as, for example, ReLU functions, and the truncation of near-zero weights to zero, which introduces a significant level of sparsity into the system. Accordingly, the technology maintains the same level of precision/accuracy for both dense and sparse compute applications.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a network controller; and
a processor coupled to the network controller, the processor including one or more substrates and logic coupled to the one or more substrates, the logic including:
a plurality of analog to digital converters (ADCs),
compute-in-memory (CiM) multiply-accumulate (MAC) hardware coupled to the plurality of ADCs, and
a plurality of digital to analog converters (DACs) coupled to the CiM MAC hardware, wherein the plurality of DACs includes one or more redundant DACs.

2. The computing system of claim 1, wherein the logic further includes a controller to:
detect a defect in the CiM MAC hardware,
disconnect an affected DAC in the plurality of DACs, wherein the affected DAC is associated with a row corresponding to the defect,
activate at least one of the one or more redundant DACs, and
remap inputs of the affected DAC to the at least one of the one or more redundant DACs.

3. The computing system of claim 2, wherein the logic further includes a plurality of switches, and wherein the affected DAC is disconnected via one or more of the plurality of switches.

4. The computing system of claim 3, wherein the plurality of switches are positioned between capacitors in the CiM MAC hardware and the plurality of ADCs.

5. The computing system of claim 1, wherein the instructions, when executed, further cause the computing system to:
detect one or more zero-valued input activations,
disconnect one or more DACs corresponding to the one or more zero-valued input activations, and
modify a scaling factor associated with the plurality of ADCs based on a number of the one or more DACs corresponding to the one or more zero-valued input activations.

6. An apparatus comprising:
one or more substrates; and
logic coupled to the one or more substrates, wherein the logic is implemented at least partly in one or more of configurable or fixed-functionality hardware, the logic including:
a plurality of analog to digital converters (ADCs);
compute-in-memory (CiM) multiply-accumulate (MAC) hardware coupled to the plurality of ADCs; and
a plurality of digital to analog converters (DACs) coupled to the CiM MAC hardware, wherein the plurality of DACs includes one or more redundant DACs.

7. The apparatus of claim 6, wherein the logic further includes a controller to:
detect a defect in the CiM MAC hardware;
disconnect an affected DAC in the plurality of DACs, wherein the affected DAC is associated with a row corresponding to the defect;
activate at least one of the one or more redundant DACs; and
remap inputs of the affected DAC to the at least one of the one or more redundant DACs.

8. The apparatus of claim 7, wherein the logic further includes a plurality of switches, and wherein the affected DAC is disconnected via one or more of the plurality of switches.

9. The apparatus of claim 8, wherein the plurality of switches are positioned between capacitors in the CiM MAC hardware and the plurality of ADCs.

10. The apparatus of claim 7, wherein the controller is further to:
detect one or more zero-valued input activations;
disconnect one or more DACs corresponding to the one or more zero-valued input activations; and
modify a scaling factor associated with the plurality of ADCs based on a number of the one or more DACs corresponding to the one or more zero-valued input activations.

11. The apparatus of claim 7, wherein the defect is detected with respect to a bitcell in the MAC hardware.

12. The apparatus of claim 7, wherein the defect is detected with respect to a capacitance in the MAC hardware.

13. The apparatus of claim 6, wherein the logic coupled to the one or more substrates includes transistor regions that are positioned within the one or more substrates.

14. At least one computer readable storage medium comprising a set of instructions, which when executed by a computing system, cause the computing system to:
detect a defect in compute-in-memory (CiM) multiply-accumulate (MAC) hardware, wherein the CiM MAC hardware is coupled to a plurality of analog to digital converters (ADCs) and a plurality of digital to analog converters (DACs), and wherein the plurality of DACs includes one or more redundant DACs;
disconnect an affected DAC in the plurality of DACs, wherein the affected DAC is associated with a row corresponding to the defect;
activate at least one of the one or more redundant DACs; and
remap inputs of the affected DAC to the at least one of the one or more redundant DACs.

15. The at least one computer readable storage medium of claim 14, wherein the affected DAC is disconnected via one or more of a plurality of switches.

16. The at least one computer readable storage medium of claim 15, wherein the plurality of switches are to be positioned between capacitors in the CiM MAC hardware and the plurality of ADCs.

17. The at least one computer readable storage medium of claim 14, wherein the instructions, when executed, further cause the computing system to:
detect one or more zero-valued input activations; and
disconnect one or more DACs corresponding to the one or more zero-valued input activations.

18. The at least one computer readable storage medium of claim 17, wherein the instructions, when executed, further cause the computing system to modify a scaling factor associated with the plurality of ADCs based on a number of the one or more DACs corresponding to the one or more zero-valued input activations.

19. The at least one computer readable storage medium of claim 14, wherein the defect is detected with respect to a bitcell in the CiM MAC hardware.

20. The at least one computer readable storage medium of claim 14, wherein the defect is detected with respect to a capacitance in the CiM MAC hardware.
